(19) United States
(12) Patent Application Publication
(10) Pub. No.: US 2003/0143819 A1
(43) Pub. Date: Jul. 31, 2003

(54) Method of producing semiconductor chips with a chip edge guard, in particular for wafer level packaging chips

(75) Inventors: Harry Hedler, Germering (DE); Roland Irsigler, Munchen (DE); Barbara Vasquez, Orinda, CA (US)

Correspondence Address: WELSH & KATZ, LTD, 120 S RIVERSIDE PLAZA, 22ND FLOOR, CHICAGO, IL, 60606, US

(73) Assignee: Infineon Technologies AG, Munchen (DE)

(21) Appl. No.: 10/336,373

(22) Filed: Jan. 3, 2003

(30) Foreign Application Priority Data
Jan. 25, 2002 (DE) 102 02 881.8

(51) Int. Cl. H01L 21/44; H01L 21/48; H01L 21/50; H01L 21/301; H01L 21/46; H01L 21/78

(52) U.S. Cl. 438/462; 438/465

(57) ABSTRACT

The present invention provides a method of producing semiconductor chips (1a, 1b, 1c; 1a′, 1b′, 1c′) with a protective chip-edge layer (21″, 22″), in particular for wafer level packaging chips, with the steps of: preparing a semiconductor wafer (1); providing trenches (21, 22) in the semiconductor wafer to establish chip edges on a first side of the semiconductor wafer (1); filling the trenches (21, 22) with a protective agent (21′; 22′); grinding back the semiconductor wafer (1) from a second side of the semiconductor wafer (1), which is opposite from the first side, to expose the trenches (21, 22) filled with the protective agent (21′; 22′); and cutting through the trenches (21, 22) filled with the protective agent (21′; 22′), so that the protective chip-edge layer (21″, 22″) comprising the protective agent (21′, 22′) remains on the chip edges.

The present invention relates to a method of producing semiconductor chips with a chip edge guard, in particular for wafer level packaging chips.

Although in principle it can be applied to any desired semiconductor chips, the present invention and the problems on which it is based are described on the basis of wafer level packaging chips.

The term “dice before grind” technology refers to a known method of individually separating semiconductor chips, in particular for wafer level packaging chips, which has the following steps:

preparing a semiconductor wafer;

providing trenches in the semiconductor wafer to establish chip edges on a first side of the semiconductor wafer; and

grinding back the semiconductor wafer from a second side of the semiconductor wafer, which is opposite from the first side, to expose the trenches and to individually separate the semiconductor chips from the semiconductor wafer.

However, this leaves the rear side of the chip and the chip edges unpassivated or mechanically and electrically unprotected after the separation has been carried out. These exposed chip rear sides and chip edges increase the risk of chip damage during handling or assembly, for example due to edge chipping.

Known wafer level packaging methods merely provide an additional protective layer on the front side of the chip, which is, for example, created on the wafer by a forming process. However, this front-side protective layer merely has the primary function of encapsulating the wiring terminals located on the front side, in order to enclose a wettable area for the solder bumps.

Rear-side protective layers for wafers using printed-on layers applied to or formed on them by a spinning process are generally known in the prior art.

It is therefore an object of the present invention to provide an improved method of producing semiconductor chips with a chip edge guard, in particular for wafer level packaging chips, whereby a reliable chip edge guard can be made in a simple way.

According to the invention, this object is achieved by the method specified in claim 1.

The idea on which the present invention is based consists in that, to establish the chip edges, the trenches are filled with a protective agent and then the trenches filled with the protective agent are cut through in such a way that the protective chip-edge layer remains on the chip edges. In this way, something of an integrated encapsulation of the chip edges is created.

The method according to the invention has the advantage over the known approaches to a solution that it offers a simple type of integrated production of a chip edge guard. Since the chip edge guard is produced at the wafer level, passivated chips can be obtained at low costs.

Advantageous developments and improvements of the subject-matter of the invention can be found in the subclaims.

According to a preferred development, the grinding back takes place before the cutting through.

According to a preferred development, the grinding back takes place after the cutting through.

According to a further preferred development, the provision of the trenches is performed by a first sawing step.

According to a further preferred development, the filling of the trenches is carried out by a dispensing step.

According to a further preferred development, the filling of the trenches is carried out by a printing step, preferably using a printing stencil or a printing screen.

According to a further preferred development, the filling of the trenches is carried out by a molding step.

According to a further preferred development, the filling of the trenches is performed in the course of applying a protective layer which covers the first side at least partially outside the trenches.

According to a further preferred development, the first side of the semiconductor wafer is applied to a carrier, preferably an adhesive film, before the grinding back.

According to a further preferred development, the second side is covered by a protective layer after the grinding back and before the individual separation.

According to a further preferred development, the cutting through of the trenches filled with the protective agent is carried out by a second sawing step, the saw blade being thinner than the width of the trenches.

According to a further preferred development, the cutting through of the trenches filled with the protective agent is carried out by a laser processing step, in particular a microjet-laser cutting step.

According to a further preferred development, the protective agent is a polymer resin, in particular polyimide, or a silicone resin.

According to a further preferred development, the semiconductor chips are wafer level packaging chips, an appropriate wiring plane being provided on the first side of the semiconductor wafer.

According to a further preferred development, the wiring plane is provided before the forming of the trenches.

According to a further preferred development, the wiring plane is provided after the filling of the trenches with a protective agent and the grinding back.

According to a further preferred development, the wiring plane has protruding contact elements.

According to a further preferred development, the filling of the trenches is performed in the course of applying a protective layer which covers the protruding contact elements at least partially outside the trenches.

An exemplary embodiment of the present invention is explained in more detail in the description which follows and is represented in the drawing, in which:

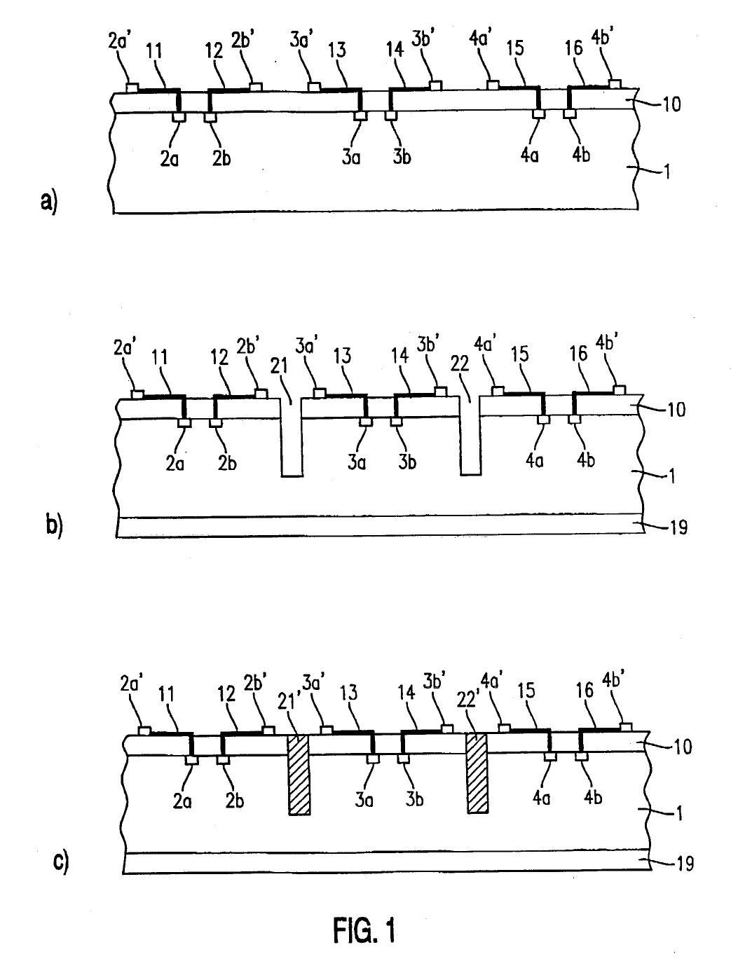

FIGS. 1a-h show eight successive stages of the method to explain a first embodiment of the method according to the invention;

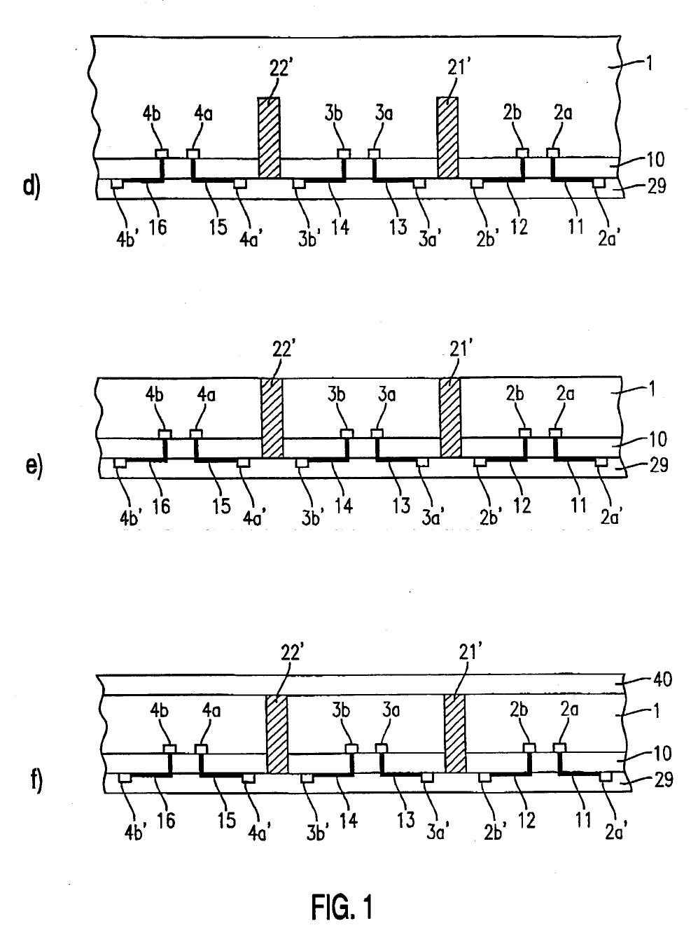

FIG. 2 shows a stage of the method analogous to FIG. 1c to explain a second embodiment of the method according to the invention;

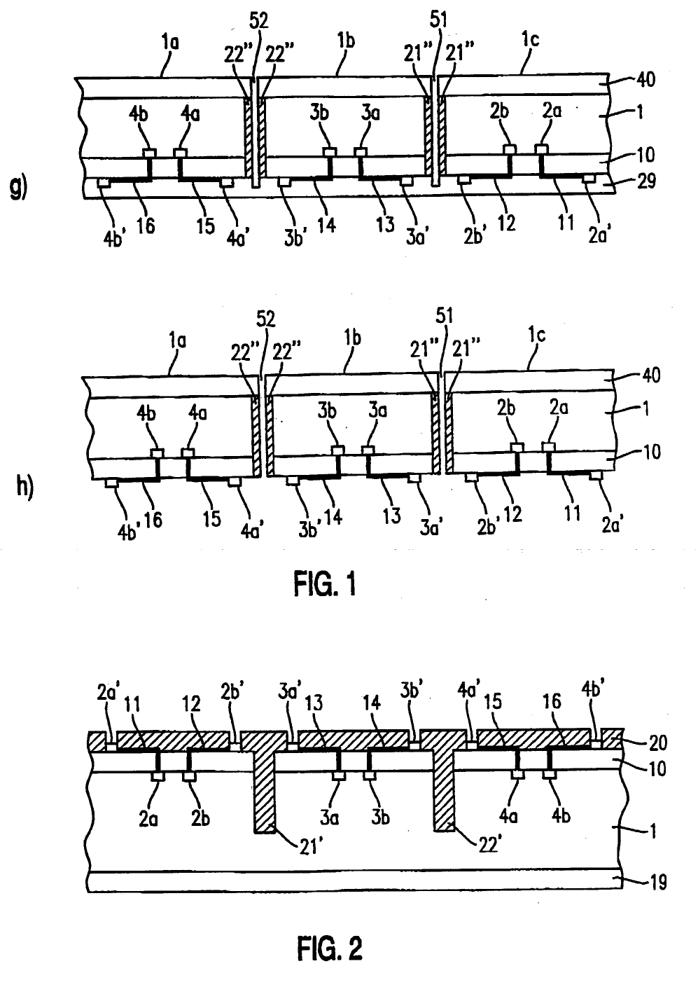

FIGS. 3a-c show three successive stages of the method to explain a third embodiment of the method according to the invention;

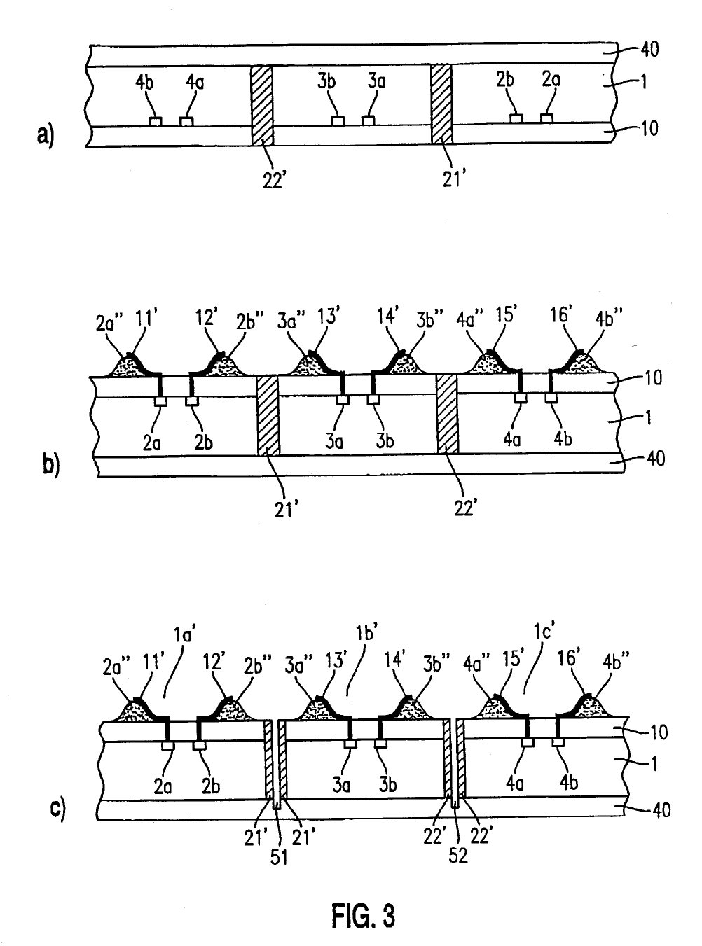

FIG. 4 shows a stage of the method analogous to FIG. 3b to explain a fourth embodiment of the method according to the invention; and

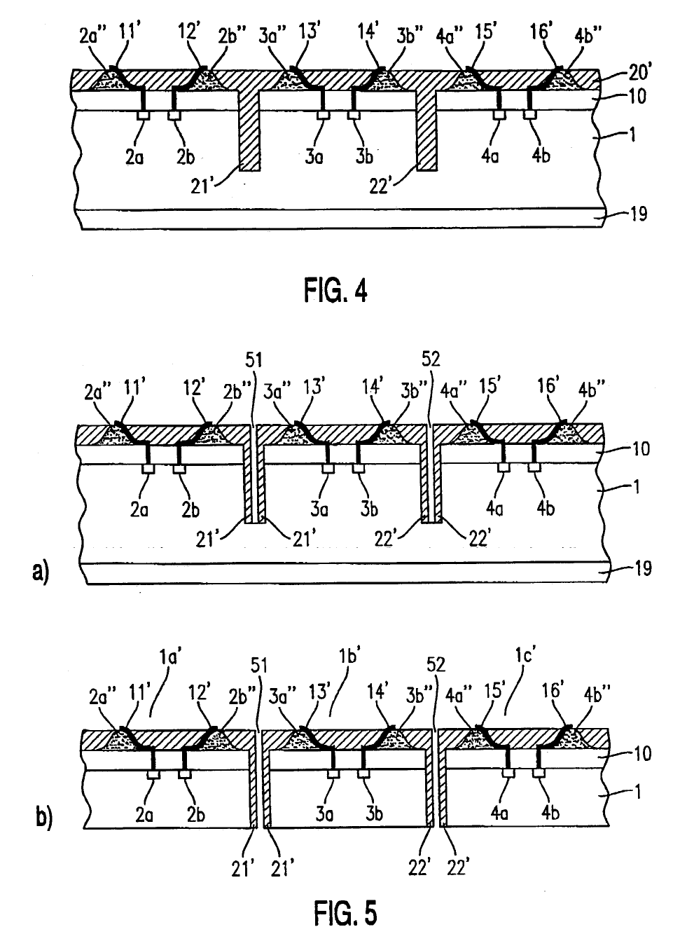

FIGS. 5a,b show two successive stages of the method to explain a fifth embodiment of the method according to the invention.

In the figures, the same reference numerals designate elements which are the same or functionally the same.

FIGS. 1a-h show eight successive stages of the method to explain a first embodiment of the method according to the invention.

In FIG. 1a, 1 designates a semiconductor wafer, which contains integrated circuits, not illustrated in any more detail, in a way corresponding to a plurality of semiconductor chips to be formed from it (cf. 1a, 1b, 1c in FIG. 1g). On the front side of the semiconductor wafer 1 there is a wiring plane which contains interconnects 11, 12, 13, 14, 15, 16, which lead from circuit terminals 2a, 2b, 3a, 3b, 4a, 4b, which are closely spaced, to circuit terminals 2a′, 2b′, 3a′, 3b′, 4a′, 4b′, which are spaced further part. The interconnects 11-16 are separated from one another in a customary way by an insulating layer 10.

According to FIG. 1b, in a first step trenches 21, 22, which serve for establishing later chip edges, are provided on the front side of the semiconductor wafer 1 with the wiring plane. The trenches 21, 22 may be created, for example, by a first sawing process, for which the semiconductor wafer 1 is adhesively applied to a corresponding sawing film, which in FIG. 2b bears the designation 19. Typical widths of the trenches 21, 22 lie in the range of 100 μm.

According to FIG. 1c, in a method step which then follows the trenches 21, 22 are filled with a passivating agent 21′, 22′, for example polyimide. This may take place by a printing step, a molding step, a dispensing step or some other customary method step. In the case of the present embodiment, the filling is performed by a printing step in conjunction with a printing stencil or a printing screen, which is not represented in FIG. 1c.

To arrive at the state of the method represented in FIG. 1d, firstly the front side of the semiconductor wafer 1 is applied to a carrier, for example an adhesive film 29, which at the same time is intended to protect the exposed circuit terminals 2a′, 2b′, 3a′, 3b′, 4a′, 4b′ on the front side and the interconnects 11-16 of the wiring layer. Moreover, pulling off of the sawing film 19 also takes place, to expose the rear side of the semiconductor wafer 1.

In the next method step, which is explained with reference to FIG. 1e, the rear side of the semiconductor wafer 1 is ground back in a customary polishing step, for example a chemical-mechanical polishing step, until the trenches 21 or 22 filled with the polyimide 21′, 22′ are exposed.

With reference to FIG. 1f, a protective layer 40 is then applied on the rear side by a customary method, for example a molding method, or some other suitable method.

In a method step explained with reference to FIG. 1g, individual separation of the semiconductor chips 1a, 1b, 1c from the semiconductor wafer 1 then takes place by the trenches 21, 22 that are filled with the protective agent in the form of polyimide 21′, 22′ being cut through by a sawing step, the thickness of the saw blade being less than the width of the trenches, so that a protective chip-edge layer 21″, 22″ on [sic] polyimide is left on the chip edges. A typical width of the separating cut for the individual separation is around typically 30 μm. In this case, the adhesive film 29 is cut into, but preferably not cut through.

In the state of the method of FIG. 1h there are individually separated semiconductor chips 1a, 1b, 1c, which are protected on the rear side by the protective layer 40 and at the chip edges by the protective layer 21″, 22″.

FIG. 2 shows a stage of the method analogous to FIG. 1c to explain a second embodiment of the method according to the invention.

According to the second embodiment shown in FIG. 2, the filling of the trenches 21, 22 with the protective agent 21′, 22′ is performed in the course of applying a front-side protective layer 20, which covers parts of the front side of the semiconductor wafer 1. It goes without saying that this front-side protective layer 20 may be printed on, dispensed or molded on, as is generally customary in the prior art.

In the case of the second embodiment, the front-side protective layer covers all the regions between the circuit terminals 2a′, 2b′, 3a′, 3b′, 4a′, 4b′and rises up a certain height above the latter.

FIGS. 3a-c show three successive stages of the method to explain a third embodiment of the method according to the invention.

In the case of the embodiment shown in FIGS. 3a-c, the production of the wiring plane on the front side, which runs partially over the protruding contact elements, only takes place after the trenches 21, 22 have been provided and filled with the protective agent 21′, 22′ and before or after the grinding back of the rear side and the optional application of the rear-side protective layer 40. This state is shown in FIG. 3a.

According to FIG. 3b, elastic elevated circuit terminals 2a″, 2b″, 3a″, 3b″, 4a″, 4b″ are then provided and have corresponding interconnects 11′, 12′, 13′, 14′, 15′, 16′ led to them, creating a connection to the chip terminals 2a, 2b, 3a, 3b, 4a, 4b through the protective layer 10.

The underlying reason why the wiring plane is only applied subsequently in the case of this third embodiment is that the raised circuit terminals 2a″, 2b″, 3a″, 3b″, 4a″, 4b″ could be damaged during the sawing or grinding-back step.

Finally, individual separation into the chips is performed according to FIG. 3c by cutting through the trenches 21, 22 filled with the protective agent 21′, 22′ and the rear-side protective layer 40 located thereunder, as in the case of the first or second embodiment.

FIG. 4 shows a stage of the method analogous to FIG. 3b to explain a fourth embodiment of the method according to the invention.

In the case of the fourth embodiment according to FIG. 4, the filling of the trenches 21′, 22″ is performed in a way analogous to that in the case of the second embodiment according to FIG. 2 in the course of applying a front-side protective layer 20′, which is provided here in conjunction with the flexible circuit terminals 2a″, 2b″, 3a″, 3b″, 4a″, 4b′ in such a way that they leave free only the tip of the contact elements with the interconnect ends of the interconnect [sic] 11′ to 16′.

The advantage in this case is that the production of the flexible and elevated contact elements or circuit terminals and the interconnects can be carried out on a thick wafer. In this case, the choice of material for the protective agent 21′, 22′, which also forms the front-side protective layer 20′, may be restricted to a flexible material such as silicone for example, in order not to lessen the elasticity of the elevated contact elements.

FIGS. 5a,b show two successive stages of the method to explain a fifth embodiment of the method according to the invention.

In the case of the fifth embodiment, shown in FIG. 5, the cutting through of the trenches 21′, 22′ filled with the protective agent takes place before the grinding-back of the rear side. In this case, the individual separation of the chips 1a′, 1b′, 1c′ is achieved by grinding back to the bottom of the trench of the trenches cut through. This alternative is shown here for the elastic circuit terminals 2a″, 2b″, 3a″, 3b″, 4a″, 4b″, although it is not restricted to them but can also be applied to other types of wiring planes.

According to FIG. 5a, in the case of the fifth embodiment cutting through of the trenches 21, 22 filled with the protective agents 21′, 22′ as far as the bottom of the respective trench takes place as from the state of the process shown in FIG. 4.

Only after that, following the detachment of the sawing film 19 and the optional application of a corresponding carrier on the front side, does the grinding-back of the semiconductor wafer 1 from the rear side take place to expose the chips 1a′, 1b′, 1c′ laterally covered by the protective agent 21′, 22′.

Although the present invention was described above on the basis of preferred exemplary embodiments, it is not restricted to these but can be modified in a variety of ways.

Although in the case of the above embodiment the step for producing the trenches or the step of cutting through the filled trenches were carried out by means of sawing techniques, other methods may also be used for this, for example laser-processing methods. For very fine cut trenches, the microjet laser-cutting method, in which the laser beam is surrounded by a water jet, is suitable in particular. It should be mentioned in this context that a narrow cut width in the separating step can be achieved all the more easily the thinner the wafer is after the polishing-back step.

It should of course be mentioned that the application of a protective layer for the front or rear side is optional and is not absolutely necessary.

It goes without saying that additional method steps may also be carried out, such as, for example, at least partial removal of the protective layer on the front side at the elastic contact elements or, for example, the use of copper layers for increasing the size of the exposed regions of the contact elements.

The method according to the invention may also be applied not only to wafer level package chips with a wiring plane but generally to any chips, for example to chips which are contacted with an anisotropic conducting adhesive by means of flip-chip technology.

List of designations

| | |
|---|---|
| 1 | semiconductor wafer |
| 10 | insulating layer |
| 2a, 2b, 3a, 3b, 4a, 4b | circuit terminals of chip 1 |
| 11-16, 11′-16′ | interconnects of the wiring |
| | plane |
| 2a′, 2b′, 3a′, 3b′, 4a′, | circuit terminals |
| 4b′ | |
| 2a″, 2b″, 3a″, 3b″, | circuit terminals |
| 4a″, 4b″ | |
| 21, 22 | trenches |
| 19 | sawing film |
| 21′, 22′ | protective agent |
| 40 | rear-side protective layer |
| 29 | adhesive film |
| 20, 20′ | front-side protective layer |
| 1a, 1b, 1c; 1a′, 1b′, 1c′ | chips |
| 51, 52 | sawing trenches |

1. Method of producing semiconductor chips (1a, 1b, 1c; 1a′, 1b′, 1c′) with a protective chip-edge layer (21″, 22″), in particular for wafer level packaging chips, with the steps of:
preparing a semiconductor wafer (1);
providing trenches (21, 22) in the semiconductor wafer to establish chip edges on a first side of the semiconductor wafer (1);
filling the trenches (21, 22) with a protective agent (21′; 22′);
grinding back the semiconductor wafer (1) from a second side of the semiconductor wafer (1), which is opposite from the first side, to expose the trenches (21, 22) filled with the protective agent (21′; 22′); and
cutting through the trenches (21, 22) filled with the protective agent (21′; 22′), so that the protective chip-edge layer (21″, 22″) comprising the protective agent (21′, 22′) remains on the chip edges.

2. Method according to claim 1, characterized in that the grinding back takes place before the cutting through.

3. Method according to claim 1, characterized in that the grinding back takes place after the cutting through.

4. Method according to one of the preceding claims, characterized in that the provision of the trenches (21, 22) is carried out by a first sawing step.

5. Method according to one of the preceding claims, characterized in that the filling of the trenches (21, 22) is carried out by a dispensing step.

6. Method according to one of the preceding claims 1 to 4, characterized in that the filling of the trenches (21, 22) is carried out by a printing step, preferably using a printing stencil or a printing screen.

7. Method according to one of the preceding claims 1 to 4, characterized in that the filling of the trenches (21, 22) is carried out by a molding step.

8. Method according to one of the preceding claims, characterized in that the filling of the trenches (21, 22) is performed in the course of applying a protective layer (20; 20′), which covers the first side at least partially outside the trenches (21, 22).

9. Method according to one of the preceding claims, characterized in that the first side of the semiconductor wafer (1) is applied to a carrier, preferably an adhesive film (29), before the grinding back.

10. Method according to claim 1, 2 or one of claims 4 to 9, characterized in that the second side is covered by a protective layer (40) after the grinding back and before the individual separation.

11. Method according to one of the preceding claims, characterized in that the cutting through of the trenches (21, 22) filled with the protective agent (21′; 22′) is carried out by a second sawing step, the saw blade being thinner than the width of the trenches (21, 22).

12. Method according to one of the preceding claims 1 to 10, characterized in that the cutting through of the trenches (21, 22) filled with the protective agent (21′; 22′) is carried out by a laser processing step, in particular a microjet-laser cutting step.

13. Method according to one of the preceding claims, characterized in that the protective agent (21′; 22′) is a polymer resin, in particular polyimide, or a silicone resin.

14. Method according to one of the preceding claims, characterized in that the semiconductor chips (1a, 1b, 1c; 1a′, 1b′, 1c′) are wafer level packaging chips and an appropriate wiring plane (10, 2a, 2b, 3a, 3b, 4a, 4b, 11-16, 2a′, 2b′, 3a′, 3b′, 4a′, 4b′; 10, 2a, 2b, 3a, 3b, 4a, 4b, 11′-16′, 2a″, 2b″, 3a″, 3b″, 4a″, 4b″) is provided on the first side of the semiconductor wafer (1).

15. Method according to one of the preceding claims, characterized in that the wiring plane (10, 2a, 2b, 3a, 3b, 4a, 4b, 11-16, 2a′, 2b′, 3a′, 3b′, 4a′, 4b′; 10, 2a, 2b, 3a, 3b, 4a, 4b, 11′-16′, 2a″, 2b″, 3a″, 3b″, 4a″, 4b″) is provided before the forming of the trenches (21, 22).

16. Method according to one of the preceding claims 1 to 14, characterized in that the wiring plane (10, 2a, 2b, 3a, 3b, 4a, 4b, 11-16, 2a′, 2b′, 3a′, 3b′, 4a′, 4b′; 10, 2a, 2b, 3a, 3b, 4a, 4b, 1l′-16′, 2a″, 2b″, 3a″, 3b″, 4a″, 4b″) is provided after the filling of the trenches (21, 22) with a protective agent (21′; 22′) and the grinding back.

17. Method according to one of claims 14 to 16, characterized in that the wiring plane (10, 2a, 2b, 3a, 3b, 4a, 4b, 11-16, 2a′, 2b′, 3a′, 3b′, 4a′, 4b′; 10, 2a, 2b, 3a, 3b, 4a, 4b, 11′-16′, 2a″, 2b″, 3a″, 3b″, 4a″, 4b″) has protruding contact elements (2a″, 2b″, 3a″, 3b″, 4a″, 4b″).

18. Method according to claim 17, characterized in that the filling of the trenches (21, 22) is performed in the course of applying a protective layer (20; 20′) which covers the protruding contact elements (2a″, 2b″, 3a″, 3b″, 4a″, 4b″) at least partially outside the trenches (21, 22).
